(19) United States
(12) Patent Application Publication
(10) Pub. No.: US 2014/0348513 A1
(43) Pub. Date: Nov. 27, 2014

(54) OPTICAL ASSEMBLY FOR OPTICAL COMMUNICATION SYSTEMS

(71) Applicant: Alcatel-Lucent USA, Inc., Murray Hill, NJ (US)

(72) Inventor: Cristian Bolle, Bridgewater, NJ (US)

(73) Assignee: Alcatel-Lucent USA, Inc., Murray Hill, NJ (US)

(21) Appl. No.: 13/901,988

(22) Filed: May 24, 2013

(51) Int. Cl. G02B 7/00; H04B 10/27; B81B 5/00

(52) U.S. Cl. CPC G02B 7/005; B81B 5/00; H04B 10/27
USPC 398/140; 359/811; 29/428

(57) ABSTRACT

An optical assembly comprising a semiconductor chip having a handle layer and a device layer on the handle layer. The device layer comprises a focusing element, a MEM device, and one or more support islands coupled to a different portion of the handle layer. One portion of the MEM device is coupled to the focusing element and another portion of the MEM device is coupled to one portion of the handle layer, and the MEM device is configured to change a physical position or orientation of the focusing element in response to an electrical actuation.

### TECHNICAL FIELD

The present disclosure is directed, to an optical assembly, communication systems using such assemblies and methods of manufacturing the same.

### BACKGROUND

This section introduces aspects that may help facilitate a better understanding of the invention. Accordingly, the statements of this section are to be read in this light and are not to be understood as admissions about what is prior art or what is not prior art.

Optical communication systems benefit from the efficient transfer of light from one device component of the system to another device component of the system. In some cases a micro-lens is used to improve light transfer by an active alignment process as part of the manufacturing process. Active alignment typically involves sending light through the lens and moving one or more of the light source component, the lens, or light receiving component, to increase the amount received light and then locking the lens and/or other components in place.

It can be difficult and time-consuming to actively align the lens and the component devices. In some cases this can be due at least in part to the variability in lens manufacture, e.g., due to the lens being cut out of a wafer and having rough sides, edges and inaccurate cut positions. Additionally, subsequent post-manufacturing misalignment between the lens and the components can be difficult or impractical to correct.

### SUMMARY

One embodiment is an optical assembly. The assembly comprises a semiconductor chip having a handle layer and a device layer on the handle layer. Different portions of the device layer are respectively shaped as a focusing element, a MEM device, and one or more support islands. One portion of the MEM device is coupled to the focusing element and another portion of the MEM device is coupled to one portion of the handle layer, and the MEM device is configured to change a physical position or orientation of the focusing element in response to an electrical actuation. The one or more support islands are coupled to a different portion of the handle layer.

In some such embodiments of the assembly, the semiconductor chip can have a through-cavity, the focusing element being located outside of the cavity and separate from the handle layer.

In any such embodiments of the assembly the focusing element, shaped as a lens, can have one side with a convex-shaped major surface and an opposite side with a planar major surface. In some such embodiments, the one side having the convex shaped major surface is farther away from the handle layer than the opposite side with the planar major surface.

In any such embodiments, the MEM device can include at least a first structure and a second structure, the first and second structures being separated from each other and at least one of the structures being moveable towards the other structure when the electrical actuation includes a voltage difference applied between the first and second structures.

Any such embodiments can further include a substrate having a surface, wherein the one or more support islands contacts the substrate surface and the focusing element is held above the substrate.

In any such embodiments the substrate can further include a cavity, a portion of the semiconductor chip being located in the cavity, and, the substrate surface that the one or more support islands contacts corresponding to a ledge surface laying outside of the substrate cavity. Any such embodiments can further include an optical device located on the substrate surface configured to send or receive a light beam, wherein the semiconductor chip is positioned on the substrate surface such that the focusing element is in a path of the light beam. Any such embodiments can further include a second optical device located on the substrate surface, wherein the light beam is from one of the optical device or the second optical device, and the focusing element is in the path of the light beam to the other of the optical device or the second optical device.

In any such embodiments at least one of the support islands can include markers and the substrate surface can include markers, at least one of the markers of the support islands being aligned with at least one of the markers of the substrate surface.

Another embodiment is an optical telecommunication system. The system comprises a first optical assembly, including a first substrate having a surface and a first set of semiconductor chips located on the first substrate surface. At least one of the semiconductor chips have a handle layer and a device layer on the handle layer. The device layer comprises a focusing element, a MEM device, and one or more support islands. One portion of the MEM device is coupled to the focusing element and another portion of the MEM device is coupled to a portion of the handle layer, and the MEM device is configured to change a physical position or orientation of the focusing element in response to an electrical actuation. The one or more support islands coupled are to a different portion of the handle layer and contact the substrate surface and hold the focusing element above the substrate. The system also includes an optical circuit configured to send or receive a first light beam wherein the first light beam passes through one of the focusing elements of the first set of semiconductor chips.

Any such embodiments of the system can further include a second optical assembly. The second assembly can include a second substrate having a surface and a second set of semiconductor chips located on the second substrate surface. At least one of the semiconductor chips has a handle layer and a device layer on the handle layer. The device layer comprises a focusing element, a MEM device, and one or more support islands. One portion of the MEM device is coupled to the focusing element and another portion of the MEM device is coupled to the handle layer, and the MEM device is configured to change a physical position or orientation of the focusing element with respect to the output light beam in response to an electrical actuation. The one or more support islands can be coupled to a different portion of the handle layer and contact the second substrate surface and holding the focusing element above the second substrate. The optical circuit can be configured to send or receive a second light beam wherein the second light beam passes through one of the focusing element of the second set of semiconductor chips. In any such embodiments, the system is configured such that: the first light beam can be transmitted through at least one of the focusing elements of the first optical assembly from one of a first set of optical devices located on the substrate. The second light beam can be transmitted through at least one of the focusing elements of the second optical assembly to one of a second set of optical devices located on the second substrate.

Any such embodiments can further include a MEM controller, wherein the MEM controller can be configured to separately apply a voltage to each one of the MEM devices of the first set of semiconductor chips.

Any such embodiment can further include light sensors configured to receive at least a portion of the input light beam after traveling through one of the focusing element of the first set of semiconductor chips.

Another embodiment is a method of manufacturing an optical communication system. The method comprises fabricating an optical assembly including providing a semiconductor chip, wherein the semiconductor chip includes a handle layer and a device layer on the handle layer. Fabricating the optical assembly includes forming, in different respective portions of the device layer, a focusing element, a MEM device, and one or more support islands. One portion of the MEM device can be coupled to the focusing element and another portion of the MEM device can be coupled to one portion of the handle layer. One or more support islands can be coupled to a different portion of the handle layer.

In any such embodiments forming the focusing element as a lens can include covering a surface of the device layer with a photoresist layer, and patterning the photoresist layer to form a photoresist portion having a perimeter that covers a portion of the device layer. In some such embodiments forming the focusing element includes partially melting the photoresist portion to form a convex-shaped photoresist portion. Some such embodiments can further include simultaneously etching the convex-shaped photoresist portion and the device layer. A convex shape can thereby be transferred to the portion of the device layer covered by the convex-shaped photoresist portion. Some such embodiments can further include removing the photoresist layer from the surface of the device layer.

In any such embodiments, forming the MEM device and the one or more support islands can include covering a surface of the device layer with a photoresist layer and patterning the photoresist layer to form openings therein to define a pattern in the photoresist layer that corresponds to the MEM device and the one or more support islands. Any such embodiments can further include etching portions of the device layer not covered by the patterned photoresist layer to thereby define the MEM device and the one or more support islands in the device layer. Any such embodiments can further include removing the photoresist layer from the surface of the device layer.

In any such embodiments forming the one or more support islands can include forming marker structures in at least one of the support islands.

Any such embodiments can include forming a through-cavity in the semiconductor chip, the focusing element being located outside of the cavity and separate from the handle layer and a portion of the MEM device is separate from the handle layer

### BRIEF DESCRIPTION OF THE DRAWINGS

The embodiments of the disclosure are best understood from the following detailed description, when read with the accompanying FIGUREs. Some features in the figures may be described as, for example, “top,” “bottom,” “vertical” or “lateral” for convenience in referring to those features. Such descriptions do not limit the orientation of such features with respect to the natural horizon or gravity. Various features may not be drawn to scale and may be arbitrarily increased or reduced in size for clarity of discussion. Reference is now made to the following descriptions taken in conjunction with the accompanying drawings, in which:

FIG. 1 presents a cross-sectional view of an optical assembly embodiment of the disclosure;

FIG. 2A presents a lens-side plan view of the assembly shown in FIG. 1 along view line 2-2 in FIG. 1;

FIG. 2B presents a lens-side plan view of the assembly shown in FIG. 1 along view line 2-2 in FIG. 1 showing a comb drive embodiment of the MEMS device;

FIG. 3 presents a back-side plan view of the assembly shown in FIG. 1 along view line 3-3 in FIG. 1;

FIG. 4 presents a cross-sectional view of an alternative optical assembly embodiment, analogous to the view presented in FIG. 1;

FIG. 5 presents a plan view of an optical assembly, such as any of the embodiments of the assemblies discussed in the context of FIG. 1-4, coupled to a substrate;

FIG. 6A presents a cross-sectional view of the semiconductor chip and substrate shown in FIG. 5 along view line 6-6 in FIG. 5;

FIG. 6B presents a cross-sectional view of the semiconductor chip and alternative substrate embodiment analogous to the view shown in FIG. 6A;

FIG. 7 presents a cross-sectional view of the semiconductor chip and substrate shown in FIG. 5 along view line 7-7 in FIG. 5;

FIG. 8 presents a diagram of an optical communication system embodiment that includes one or more of the optical assemblies such as any of the optical assemblies discussed in the context of FIGS. 1-7;

FIG. 9 presents a flow diagram of a method of manufacturing the optical assembly and optical communication system such as any of the assemblies and systems discussed in the context of FIGS. 1-8; and

FIGS. 10-17 present cross-sectional views of an optical assembly of the disclosure, analogous to the optical assembly embodiment shown in FIG. 2B at a selected steps in the method of manufacture discussed in the context of FIG. 9.

In the Figures and text, similar or like reference symbols indicate elements with similar or the same functions and/or structures.

In the Figures, the relative dimensions of some features may be exaggerated to more clearly illustrate one or more of the structures or features therein.

Herein, various embodiments are described more fully by the Figures and the Detailed Description. Nevertheless, the inventions may be embodied in various forms and are not limited to the embodiments described in the Figures and Detailed Description of Illustrative Embodiments.

### DETAILED DESCRIPTION

The description and drawings merely illustrate the principles of the inventions. It will thus be appreciated that a person of ordinary skill in the relevant arts will be able to devise various arrangements that, although not explicitly described or shown herein, embody the principles of the inventions and are included within its scope. Furthermore, all examples recited herein are principally intended expressly to be for pedagogical purposes to aid the reader in understanding the principles of the inventions and concepts contributed by the inventor(s) to furthering the art, and are to be construed as being without limitation to such specifically recited examples and conditions. Moreover, all statements herein reciting principles, aspects, and embodiments of the inventions, as well as specific examples thereof, are intended to encompass equivalents thereof. Additionally, the term, “or,” as used herein, refers to a non-exclusive or, unless otherwise indicated. Also, the various embodiments described herein are not necessarily mutually exclusive, as some embodiments can be combined with one or more other embodiments to form new embodiments.

Embodiments of the present disclosure provide an optical assembly comprising a focusing element, a micro-electro-mechanical (MEM) device and one or more support islands, all fabricated from a same unitary semiconductor device layer. The resulting unitary optical assembly facilitates the precision alignment of a light beam traveling between optical device components of optical communication systems. Because the focusing element, MEM device and support islands are formed from the same device layer in shared processing steps, fabrication is simplified, and, the positions of these features relative to each other can be precisely controlled. In some cases, as part of the fabrication process, marker structures can be formed within the support island to facilitate passive alignment between the focusing element and other device components on a substrate. Moreover, the MEM device can be used to fine-tune alignment of the light beam via active alignment, or in some cases, to subsequently realign the light beam for the optical assembly post-manufacturing.

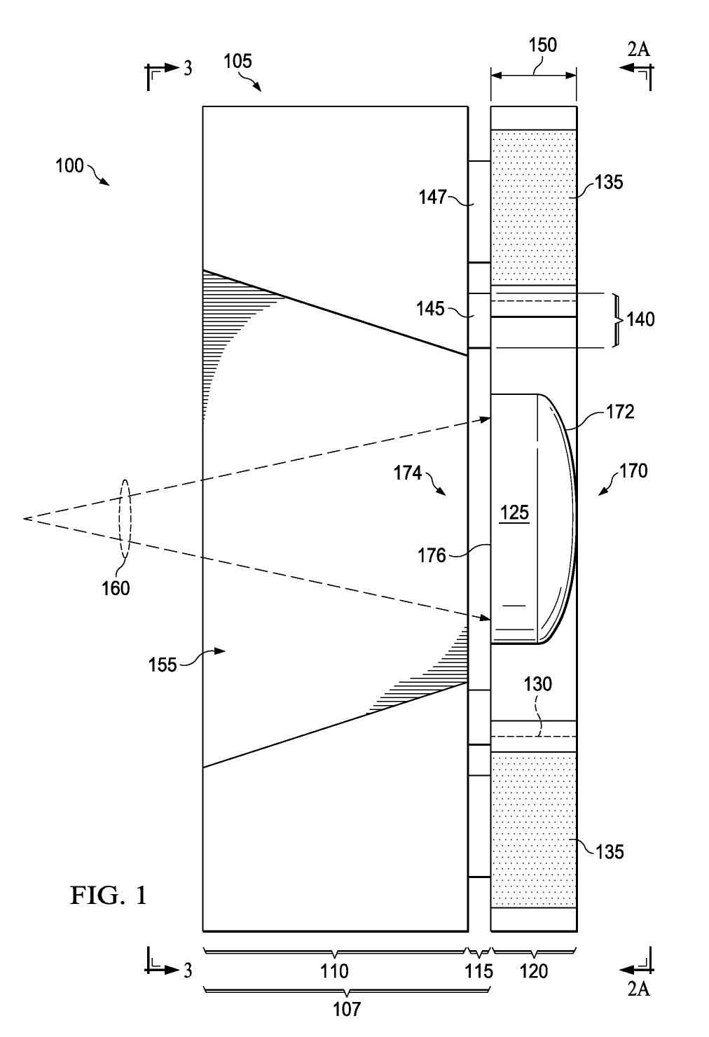

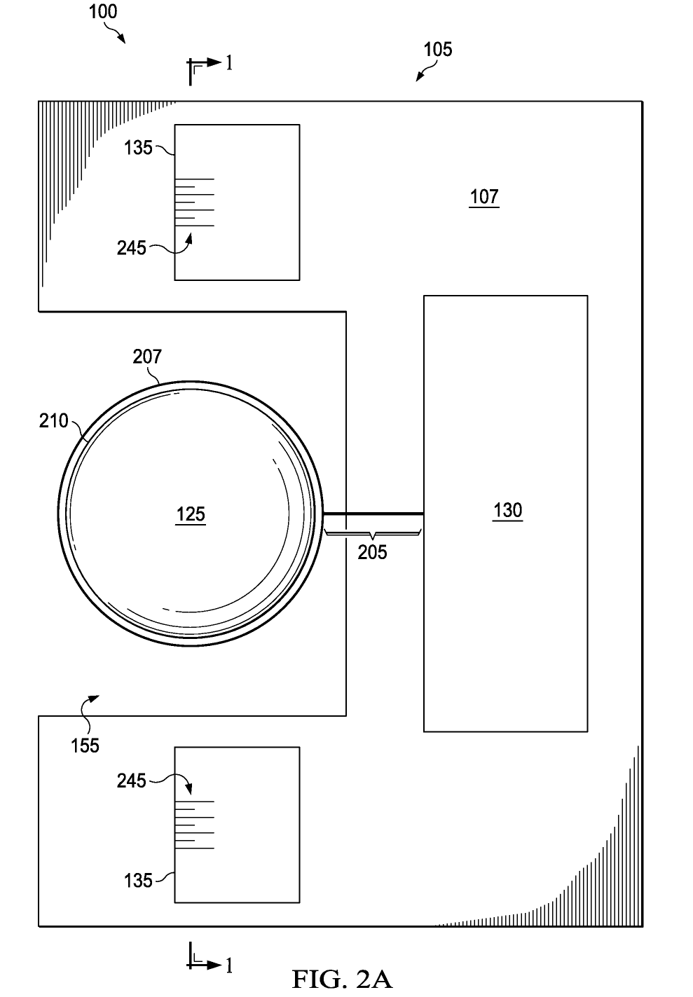

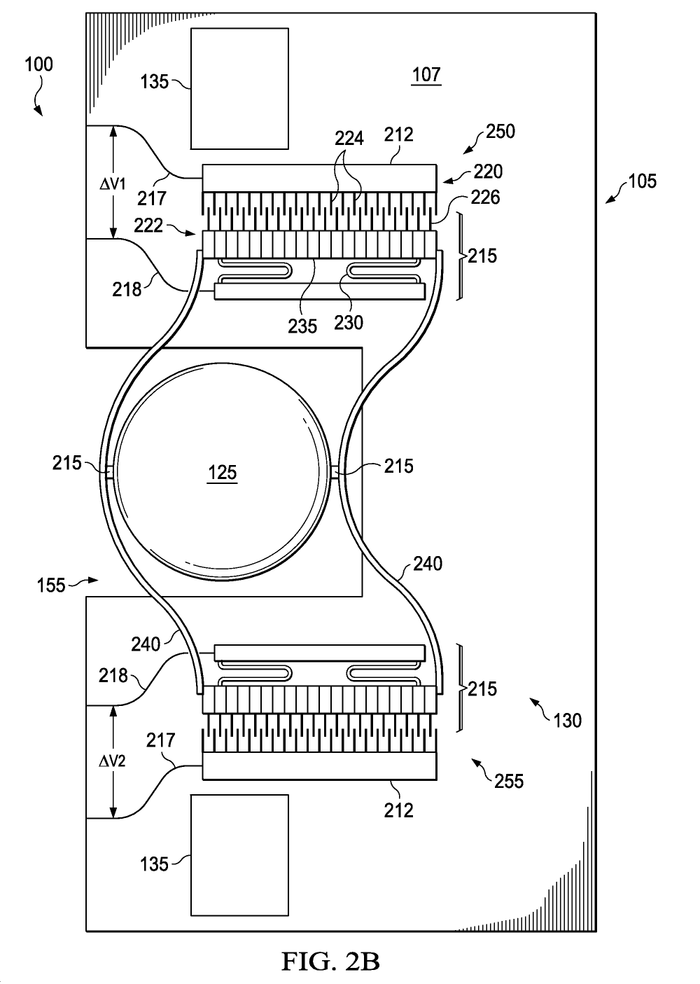

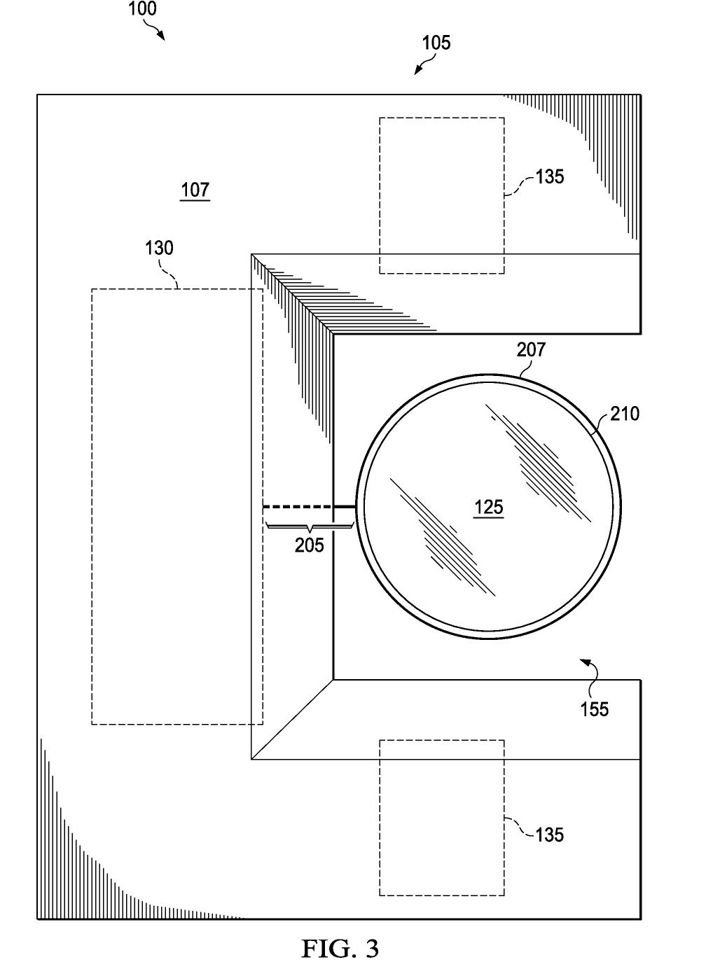

One embodiment of the disclosure is an optical assembly. FIG. 1 presents a cross-sectional view of an optical assembly 100 embodiment of the disclosure. FIG. 2A presents a lens-side plan view of the assembly 100 shown in FIG. 1 along view line 2-2 in FIG. 1. FIG. 3 presents a back-side plan view of the assembly 100 shown in FIG. 1 along view line 3-3 in FIG. 1.

With continuing reference to FIGS. 1 and 2, the optical assembly 100 comprises a semiconductor chip 105 having a handle layer 107. The term handle layer, as used herein, refers to a semiconductor layer of the chip 105 that is held during the manufacturing or positioning of the optical components of a device layer that facilitates the function of the chip 105 in the assembly 100, but, which is not part of those optical components. In some cases, the handle layer 107 includes, or is, a silicon layer 110 and a silicon oxide layer 115. In other cases, the handle layer 107 includes, or is, a sapphire layer. The semiconductor chip 105 also has a device layer 120 on the handle layer 107. The term device layer, as used herein, refers to another semiconductor layer of the chip 105 that includes the optical components of the chip 105 as further disclosed below. In some cases, the device layer 120 includes, or is, another semiconductor layer such as a crystalline semiconductor layer (e.g., a crystalline silicon layer). In some cases, the device layer 120 is grown (e.g., an epitaxially grown crystalline semiconductor layer) on the handle layer 107. In other cases, the device layer 120 can be grown on a different layer (e.g., a seed layer) and then transferred to the handle layer 107. Those skilled in the pertinent arts will appreciate that handle layer 107 and the device layer 120 can include a wide variety of types of semiconductor materials commonly found in semiconductor devices.

The device layer 120 comprises a focusing element 125, a MEM device 130 and one or more support islands 135. For instance, in some embodiments, different portions of the device layer 120 are respectively shaped as: a focusing element 125, a MEM device 130 and one or more support islands 135. One portion of the MEM device 130 is coupled to the focusing element 125 and another portion of the MEM device 130 is coupled to one portion of the handle layer 107, and the MEM device 130 is configured to change a physical position or orientation of the focusing element 125 in response to an electrical actuation. For instance in some embodiments, one portion 205 of the MEM device 130 is coupled to the focusing element 125 and another portion 140 of the MEM device 130 is coupled to a portion 145 of the handle layer 107 (e.g., in some cases, coupled to the handle silicon layer 110 via the silicon oxide layer 115). The MEM device 130 changes a physical position or orientation of the focusing element 125 (e.g., a physical position or orientation with respect to a light beam) when the MEM device 130 is electrically actuated. The one or more support islands are coupled to another different portion 147 of the handle layer 107 (e.g., in some cases the handle silicon layer 110 via the silicon oxide layer 115).

As illustrated in FIG. 1, the focusing element 125, MEM device 130 and one or more support islands 135 are co-aligned, e.g., in a common plane, and in some cases, can all have a same thickness, corresponding to a thickness 150 of the device layer 120.

As illustrated in FIG. 1, in some embodiments, the semiconductor chip 105 is a silicon-on-insulator chip, wherein the handle layer 107, includes or is, a silicon handle layer 110 and a silicon oxide layer 115 on the handle silicon layer 110, and, the device layer 120 is a silicon layer on the silicon oxide layer 115.

In other embodiments the semiconductor chip 105 is a silicon-on-glass chip, wherein the handle layer 107, includes or is, a glass handle layer, and, the device layer 120 is a silicon layer. Based on the disclosure one skilled in the pertinent art would appreciate that the semiconductor chip 105 could comprise other semiconductor material layers.

In some embodiments of the assembly 100, such as illustrated in FIGS. 1-3, the semiconductor chip 105 can have a through-cavity 155, e.g., to allow unobstructed optical access to focusing element 125. As further illustrated, for some such embodiment the focusing element 125 is located outside of the cavity 155 and is separate, or free, from the handle layer 107 (e.g., in some cases, the silicon oxide layer 115 and the handle silicon layer 110). Providing a through-cavity 155 can facilitate efficient light transmission of a light beam 160 through the focusing element 125 without the light beam 160 being absorbed or reflected by the handle layer 107, and, thereby avoid the need for additional fabrication expenses to cover handles layer 107 (or component layers 110, 115) with an antireflective coating.

As illustrated in FIG. 2, in some embodiments the focusing element 125 includes a frame 207 (e.g., a ring-shape frame) shaped from the device layer 120 and configured to to hold a lens 210, e.g., a separate lens made of different a material that the device layer 120. Non-limiting examples include glass silicon, sapphire or other materials familiar to those skilled in the pertinent arts. In some cases, the lens 210 and/or frame 207 can be coated with an antireflective coating. In other embodiment the focusing element 125 include a unitary frame and lens 207, 210 both shaped from the device layer 120.

As also illustrated in FIG. 1, in some embodiments, to facilitate focusing the light beam 160, one side 170 of the focusing element 125, shaped as or configured as a lens 210, has a convex-shaped major surface 172 and an opposite side 174 of the lens 210 includes a planar major surface 176. In some embodiments, to reduce optical losses, the planar major surface 172 is configured to face a light source optical device configured to send a light beam 160 through focusing element 125 (e.g., the lens 210). In some cases, as illustrated in FIG. 1, the one side 170 having the convex shaped major surface 172 is farther away from the handle layer 107 than the opposite side 174 with the planar major surface 176.

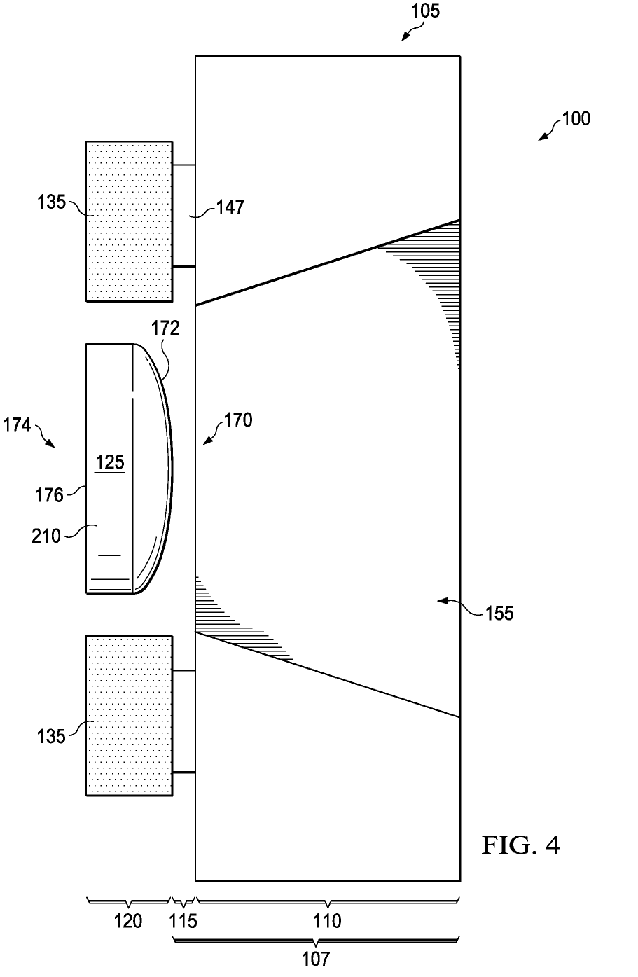

FIG. 4 presents a cross-sectional view of an alternative optical assembly 100 embodiment, analogous to the view presented in FIG. 1. For clarity, the MEM device is not depicted in the figure. As illustrated in FIG. 4, the one side 170 having the convex shaped major surface 172 is closer to the handle layer 107 than the opposite side 174 with the planar major surface 176.

Providing an assembly 100 embodiment where the convex shaped major surface 172 on the side 170 facing farther away from the handle layer 107, as illustrated in FIG. 1, can be simpler to fabricate than an assembly embodiment with the inverse orientation such as illustrated in FIG. 4. For instance, in some cases, the lens 210 having the convex shaped major surface 172 oriented as shown in FIG. 1 can be fabricated in a shorter number of steps than the lens 210 having the convex shaped major surface 172 oriented as shown in FIG. 4. For instance, in some embodiments, to fabricate the chip 105 such as shown in FIG. 4, an original handle layer bonded to the device layer 120 side 174 with the planar lens surface 176 is removed, a new handle layer is bonded to the device layer 120 side 170 with the convex shaped surface 172 and a cavity 155 is etched into the replacement handle layer 107.

In some embodiments, the MEM device 130 can include one or more electrostatic comb drives, or other actuators familiar to those skilled in the pertinent art. FIG. 2B presents a lens-side plan view of the apparatus 100 shown in FIG. 1 analogous to the view presented in FIG. 2A, showing a comb drive embodiment of the MEMS device 130.

As illustrated in FIG. 2B, in some embodiments, the MEM device 130 includes at least a first structure 212 and a second structure 215, the first and second structures 212, 215 being separated from each other (e.g., physically separated in space) and at least one structure 212, 215 (e.g., structure 215 in some cases), or portion thereof, being moveable towards the other structure 212, 215 (e.g., structure 212 in some cases) when electrically actuated, e.g., by applying a voltage difference (ΔV), e.g., via electrical lines 217, 218 between the first and second structures 212, 215.

As further illustrated, in some embodiments, the first structure 212 can include a fixed comb 220 and the second structure 215 can include a movable comb 222. Fingers 224 of the fixed comb 220, can moveably inter-digitate with fingers 226 of the movable comb 222. The second structure 215 can further include a spring 230 coupled to a body 235 holding the fingers 226 of the movable comb 222. In some embodiments, when the voltage difference (ΔV1) between the first and second structures 210, 215 is increased, the movable comb 222 moves towards the fixed comb 220. In some embodiments, when the voltage difference (ΔV1) is decreased, the spring 230 can push the movable comb 222 away from the fixed comb 220.

To facilitate actuation of the focusing element 125, one or more flexible beams 240 can be coupled to the body 235 and to the focusing element 125. In some cases, to facilitate more precise actuation of the focusing element 125, there can be two of more (e.g., opposing) comb drive sets 250, 255 of the second structures 215 of each set 250, 255 coupled to the same flexible beams 240. In some embodiments, when a voltage (ΔV2) is applied to the second set 255, the first and second structures 212, 215 of the second set 255 are pulled together, which in turn, results in the focusing element 125 moving diagonally to the upper right with respect to the view shown in the figure. When a voltage (ΔV1) is applied to the first set 250 the first and second structures 212, 215 of the first set 250 are pulled together, which in turn, results in the focusing element 125 moving diagonally to the upper left, with respect to the view shown in the figure. If voltages (ΔV1, ΔV2) are applied to both sets 250, 255, the focusing element 125 moves upwards, with respect to the view shown in the figure.

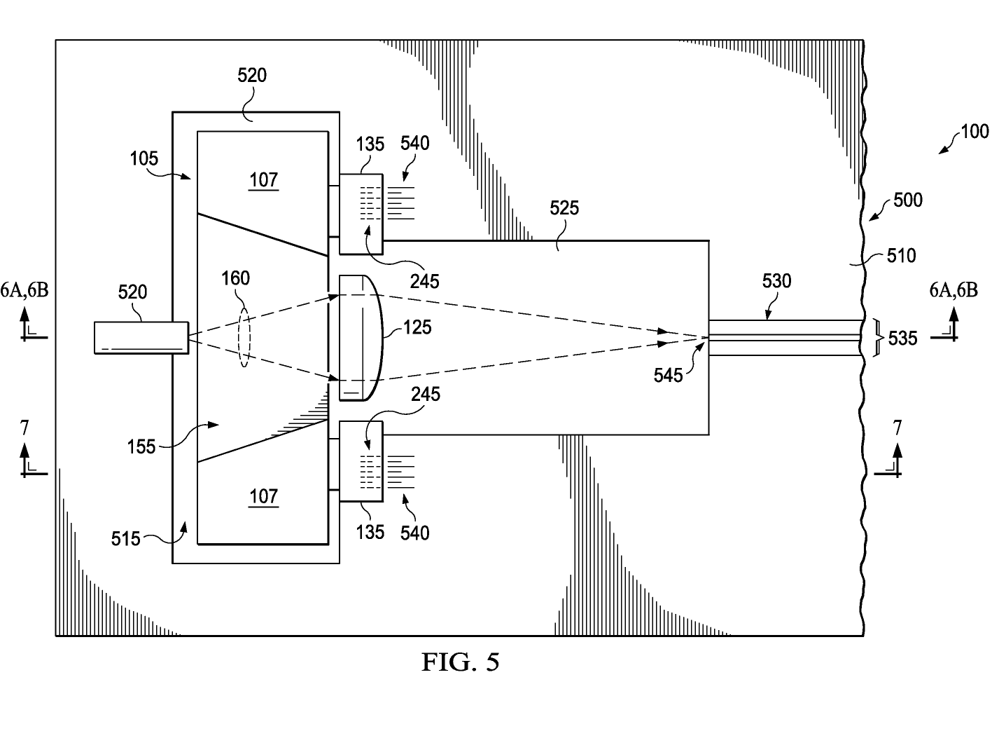

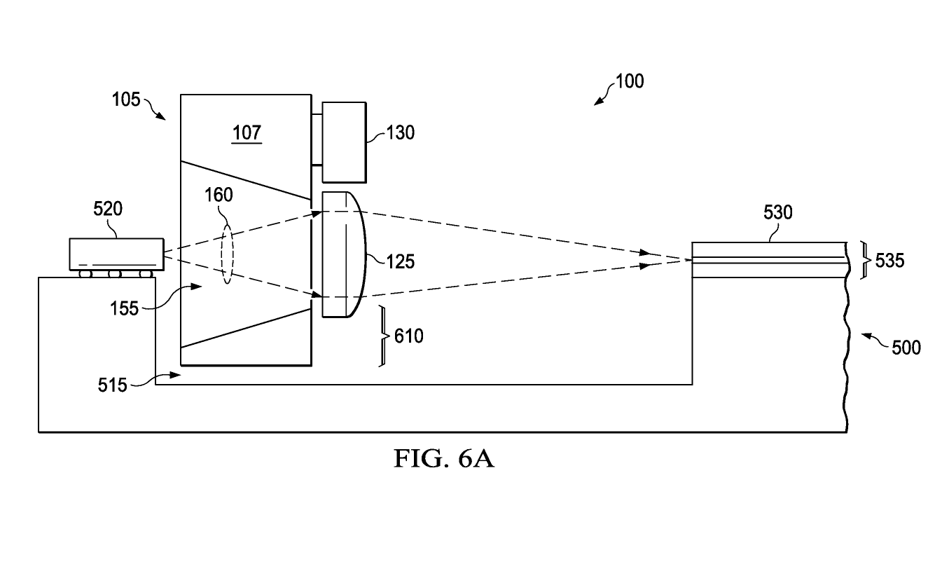

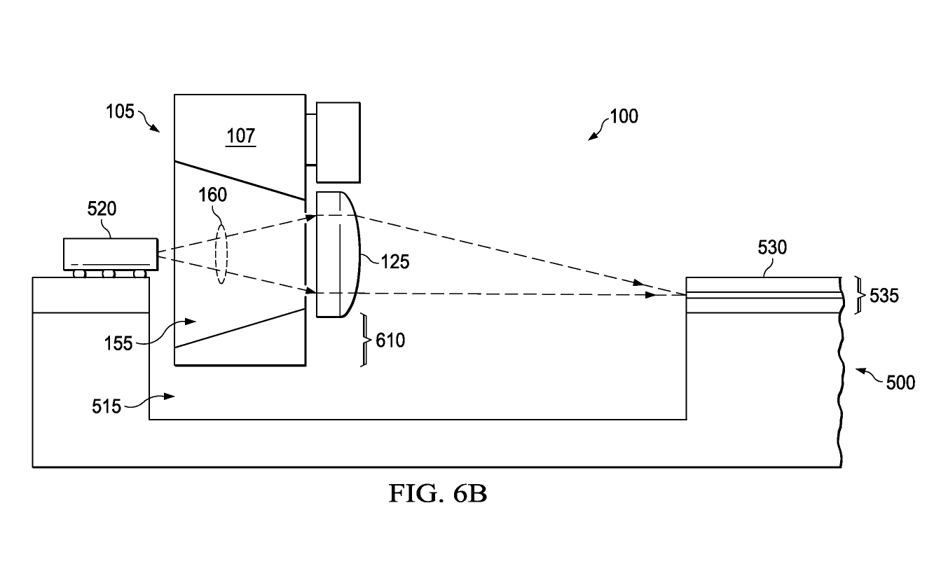

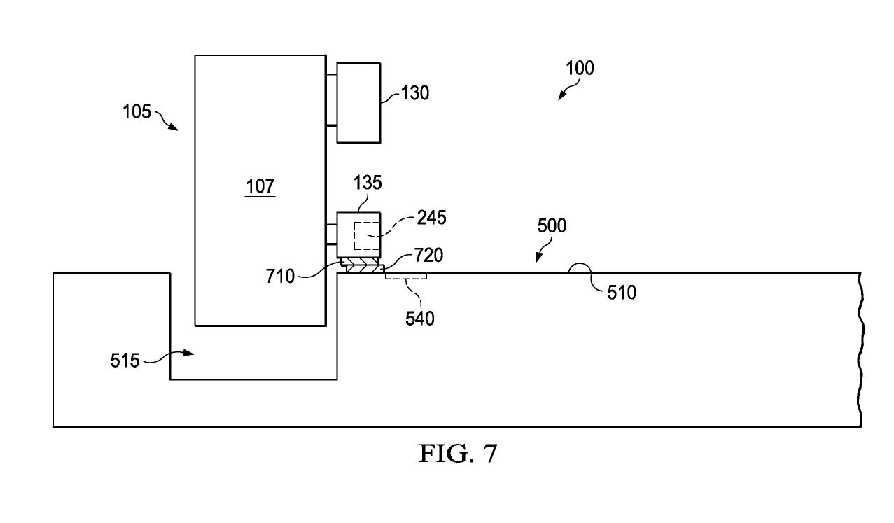

FIG. 5 presents a plan view of an optical assembly, such as any of the embodiments of assemblies 100 discussed in the context of FIGS. 1-4, showing the semiconductor chip 105 coupled to a substrate 500 of the assembly. FIG. 6A presents a cross-sectional view of the chip 105 and substrate 500 shown in FIG. 5 along view line 6-6 in FIG. 5. FIG. 7 presents a cross-sectional view of the chip 105 and substrate 500 shown in FIG. 5 along view line 7-7 in FIG. 5.

In some embodiments, the substrate 500 can include or be a silicon substrate, including a silicon-on-insulator substrate, while in other cases, the substrate can include or be another semiconductor material (e.g., glass or silicon on glass), or yet other material (e.g., metal or plastic) familiar to those skilled in the pertinent arts.

As illustrated, the substrate 500 has a surface 510 (e.g., a planar surface in some cases), and the one or more support islands 135 contact the substrate surface 510 and the focusing element 125 is held (e.g., thereby held) above the substrate 500. In some such embodiments, the major surfaces 170, 172 of the focusing element 125 are substantially perpendicular to the surface 510.

As further illustrated, in some embodiments, to provide a more compact assembly, the substrate 500 can further include a cavity 515. In such embodiments a portion 610 of the semiconductor chip 105 can be located in the cavity 515 (FIGS. 6A and 6B). In some such embodiments, the substrate surface 510 that the one or more support islands 135 contacts corresponds to a ledge surface laying outside of the substrate cavity 515.

In some embodiments, to facilitate providing a compact semiconductor chip 105, the substrate cavity 515 can have a t-shape in the plan view illustrated in FIG. 5. As illustrated, portions of the handle substrate layer 110 can be located in a cross portion 520 of the t-shaped cavity 515. Portions of the focusing element 125 can be located in a stem portion 525 of the t-shaped cavity 515. The one or more support islands 135 can rest on ledge surfaces 510 defining the cross portion 520 of the t-shaped cavity 515.

As illustrated in FIG. 7, to fix the chip 105 to the substrate 500 the one or more support islands 135 can be coupled to the ledge surface 510. In some cases matching metallization layers 710, 720 (e.g., solder layers) on the support islands 135 and surface 510 can be melted together. In other cases, the support islands 135 and surface 510 can be glued together with an adhesive such as epoxy.

As further illustrated in FIGS. 5, 6A and 7, in some embodiments, the assembly 100 further includes an optical device 520 located on the substrate surface 510. In some embodiments, the device 520 is configured to send or receive a light beam 160, wherein the semiconductor chip 105 is positioned on the substrate surface 510 such that the focusing element 125 is in a path of the light beam 160. In some embodiments, the semiconductor chip 105 is positioned on the substrate surface 510 such that the focusing element 125 is in a path of a light beam 160 coming to or from the optical device 520. In some embodiments, the light beam 160 include light of one or more wavelengths in ranges typically used in optical communications, e.g., the S band (1460 nm-1530 nm), the C band (1530 nm-1565 nm) or the L band (1565 nm-1625 nm) ranges.

In some embodiments, the light beam 160 can come from a light source external to the assembly 100 and travel to the optical device 510. In other embodiments, the light beam 160 can be generated by the optical device 520 configured as a light source. For instance, in some cases the optical device 520 can be or include a laser light source (e.g., a laser diode), that can be, e.g., flip-chip bonded to the substrate surface 510.

In some cases, the optical device 520 can be or include a light detector (e.g., photodiode or waveguide detector, InP optical detectors), a waveguide (e.g., fiber waveguide, or rectangular waveguide), optical modulator (e.g., LiNb optical modulators), optical amplifier (e.g., semiconductor optical amplifier) or other optical device used in optical communication systems as familiar to those skilled in the pertinent arts.

As further illustrated in FIGS. 5, 6A and 7 in some embodiments, the assembly 100 further includes a second optical device 530 located on the substrate surface 510. In some embodiments, the light beam 160 is from one of the optical device 520 or the second optical device 530, and the focusing element 125 is in the path of the light beam 160 to the other of the optical device 520 or the second optical device 530. In some cases, such as when the light beam 160 is from one of the optical devices 520, 530 (e.g., device 520), the light beam 160 can travel through the focusing element 125 to the other optical devices 520, 530 (e.g., device 530).

In some cases, the second optical device 530 can be or include a waveguide configured to receive the light beam 160 after traveling through the focusing element 125. For instance, in some cases, the second optical device 530 can be a waveguide formed from a silicon layer 535 located on the substrate 500. In some cases, such as illustrated in FIG. 6B, the first optical device 520, configured as a light source 520, can be located on a portion of the silicon layer 535.

As illustrated in FIGS. 2A, 5 and 7, to facilitate passive alignment of the focusing element 125 and the optical devices 520, 530, at least one of the support islands 135 can include markers 215 and the substrate surface 510 includes markers 540. In some embodiments, to facilitate passive alignment, at least one of the markers 215 of the support islands 135 is aligned with at least one of the markers 540 of the substrate surface 510.

In some embodiments, the markers 215 of the support islands 135 meet the markers 540 on the substrate surface 510 to form a substantially perpendicular angle. In some such embodiments, the chip 205 is on the substrate surface 510 such that the markers 215 of the support islands 135 are oriented perpendicular to the markers 540 on the substrate surface 510.

In some embodiments, the perpendicular orientation of the support island markers 215 relative to the substrate markers 540 helps to reduce the number of degrees of freedom of movement necessary to passively align the semiconductor chip 105 with the substrate 500. For instance, in some cases by placing support island markers 215 near or at the edge of the support island 135 and the substrate markers 540 centrally on the planar surface 540 can facilitate the simple and rapid placement of the chip 105 on the substrate 500, e.g., in some cases with translation of the chip 105 only in in one dimension over the surface 510 until the two markers 215, 540 align,

In some embodiments, the markers 215, 540 are one or more straight trenches formed in the support islands 135 and substrate surface 510. In some case, the markers 215 configured as straight trenches can be formed as part of etching steps to define the shapes of the focusing element 125, MEM device 130 and support islands 135. In other embodiments, the markers, can be configured as straight raised portions, e.g., of deposited materials or non-etched materials layers of the support islands or substrate surface 510. In still other embodiments, the markers 215 can be formed as trenches in the support islands 135 designed to mate with the markers 540 formed as raised portions on the substrate surface 510. Based on the present disclosure, one skilled in the art would appreciate that other marker configurations could be used.

In some embodiments, after the markers 215, 540 are passively aligned, a subsequently applied light beam 160 traveling between the first device 520 and second device 530 lands on a target area 545 of second device 530 (e.g., in some cases, the receiving face 545 of a waveguide optical device 530) within about 10 microns, and in some cases, within about 5 microns, and in some cases, within about 2 microns of the center of the target area 545. However, in other embodiments, the markers 215, 540 could be used in conjunction with an active alignment procedure.

In some embodiments, after passive alignment, the alignment can be fine-tuned in an active alignment procedure, where, e.g., the MEM device 130 is actuated to change the physical position or orientation of the focusing element 125 around based on feedback which includes information about the intensity of the light beam 160 traveling through the focusing element 125 and reaching the target area 545. For instance, in some embodiments, following such active alignment, the light beam 160 traveling between the first device 520 and second device 530 lands on a target area 545 of second device 530 (e.g., the receiving face 545 of a waveguide optical device 530) within about 2 microns, and in some cases, within about 1 microns, and in some cases, within about 0.5 microns of the center of the target area 545.

In some cases, after passive and active alignment the focusing element 125 and/or MEM device 130 can be locked (e.g., via glue or welding) into the position that orients the focusing element 125 to increase the amount of light reaching the target area 545. In other cases, the MEM device 130 can be left moveable. In such cases, the MEM device 130 can be configured to be actuated in the finally-constructed assembly 100 to adjust for misalignments in the focusing element 125, e.g., due to environment temperature variations in the assembly 100 when in field use. In other embodiments, the MEM device 130 can be actuated in the final-constructed assembly 100 to intentionally adjust the focusing element′ 125 orientation, e.g., to attenuate the intensity of the light beam 160 reaching the target area 545, or, to redirect the light beam 160 to the target area of a different optical device on the substrate 500.

As illustrated in FIGS. 5-7 in some cases the first and second optical devices 520, 530 and the semiconductor chip 105 are all located on a same substrate 500 of the assembly 100. Such a configuration can simplify the assembly's fabrication and the alignment procedures. For instance, in some embodiments with one substrate 500, there need only be one set of markers 215 on the support islands 130 and one set of markers 540 on the substrate surface 510. In embodiments, where one or more of the first and second optical devices 520, 530 and the semiconductor chip 105 are located different substrates, there may be a need for multiple alignment markers on the substrates to facilitate passive alignment between the different substrate.

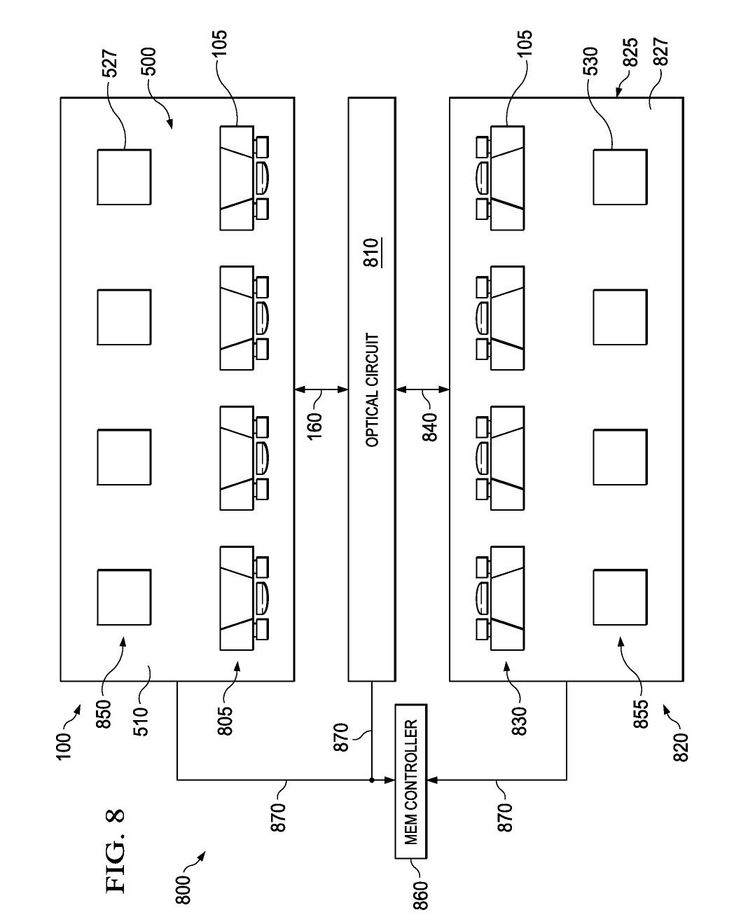

Another embodiment is an optical telecommunication system. FIG. 8 presents a diagram of an optical communication system 800 embodiment that includes one or more of optical assemblies such as any of the optical assemblies 100 discussed in the context of FIGS. 1-7.

As illustrated in FIG. 8, with continuing reference to FIGS. 1-7 throughout, the system 800 comprises a first optical assembly 100 that includes a first substrate 500 and a first set 805 of semiconductor chips 105 (e.g., in some cases an array of chips) located on the first substrate surface 510. The first set 805 of semiconductor chips 105 can include any of the embodiments, or combinations of different embodiments, of the semiconductor chips 105 discussed in the context of FIGS. 1-7. At least one of, and in some cases, each, of the semiconductor chips 105 have the handle layer 107, and the device layer 120 (FIG. 1). The device layer comprises focusing element 125, MEM device 130 and support islands 135. For instance in some embodiments, portions of the device layer 120 are shaped as embodiments of the focusing element 125, MEM device 130 and support islands 135 as discussed in the context of FIGS. 1-7.

The system 800 further comprises an optical circuit 810 configured to send or receive a first light beam 160 wherein the first light beam 160 passes through at least one of the focusing element 125 of the first set 805 of semiconductor chips 105.

The optical circuit 810 can be any optical circuit chip (e.g., a photonic circuit) used in telecommunication systems to receive, modulate or transmit information via light. Without limitation, for example, the circuit 810 can include optical couplers, splitters, multiplexors and de-multiplexors, optical taps or other components familiar to those skilled in the pertinent arts.

As further illustrated in FIG. 8, in some embodiments, the system 800 further includes a second optical assembly 820. The second assembly 820 includes a second substrate 825 having a surface 827, and, a second set 830 of semiconductor chips 105 (e.g., in some cases, an array of chips) located on the second substrate surface 827. Analogous to that discussed above for the first set 805, the second set 830 of semiconductor chips 105 can include any of the embodiments or combinations of embodiments of the semiconductor chips 105 discussed in the context of FIGS. 1-7. Analogous to the chips 105 of the first set 805, at least one, and in some cases, each, of the chips 105 of the second set 830 have a handle layer and a device layer on the handle layer (FIG. 1). Different portions of the silicon layer are respectively shaped as focusing elements, electrically actuatable MEM devices, and support islands holding the focusing element above the second substrate, such as disclosed in the context of FIGS. 1-7.

In some such embodiments of the system 800, the system 800 (e.g., in some cases, the optical circuit 810) can be configured to send or receive a second light beam 840, wherein the second light beam 840 can pass through at least one of the focusing element of the second set 830 of semiconductor chips 105.

In some embodiments of the system 800 the first light beam 160 (e.g., an input light beam) can be transmitted through at least one of the focusing elements 125 to the first optical assembly 100 from one of a first set 850 of optical devices 520 located on the substrate 500. In such embodiments, the second light beam 840 (e.g., an output light beam) can be transmitted through at least one of the focusing elements 125 of the second optical assembly 820 to one of a second set 855 of optical devices 530 located on the second substrate 825.

In some cases the first set 850 of optical devices 520 can include all of the same type of optical devices (e.g., arrays of all light sources, light sensors or waveguides) while in other cases the optical devices 520 can include mixtures or combinations of different types of optical devices. Similarly, the second set 855 of optical devices 530 can be all of the same type of optical devices in some cases, while in other cases, the optical devices 530 can include mixtures or combinations of different types of optical devices.

As further illustrated in FIG. 8, in some embodiments the system 800 includes a MEM controller 860. The MEM controller 860 is configured to separately apply a voltage to each one of the MEM devices 130 first set 805 of semiconductor chips 105, or when present, each one of the MEM devices 130 of the second set 830 of semiconductor chips 105.

As also illustrated in FIG. 8, in some embodiments, the system 800 includes light sensors, e.g., as part of the optical devices 520, 530, optical circuit 810, or in other cases, as separate devices. The sensors are configured to receive at least a portion of the first light beam 160 after traveling through one of the focusing elements 125 of the first set 805 of semiconductor chips 105, or when present, to receive at least a portion of the second light beam 840 after traveling through one of the focusing elements 125 of the second set 830 of semiconductor chips 105. The sensors are configured to provide a feedback signal 870 to the MEM controller 860. The feedback signal 870 is proportional to the intensity of the first or second light beam 160, 840 reaching an target area 535 of one of an optical devices 520, 530 on the first or second substrate 500, 825 or of the optical circuit 810 after traveling through one of the focusing elements 125 of the first or second sets 805, 830 of semiconductor chips 105.

In some embodiments, e.g., as part of an active alignment procedure, the MEM controller 860 can be configured to separately adjust the voltage applied to each one of the MEM devices 130 of first set 805 of semiconductor chips 105, or when present, or to the MEM devices 130 of the second set 830 of semiconductor chips 105, to increase the intensity of the feedback signal 870.

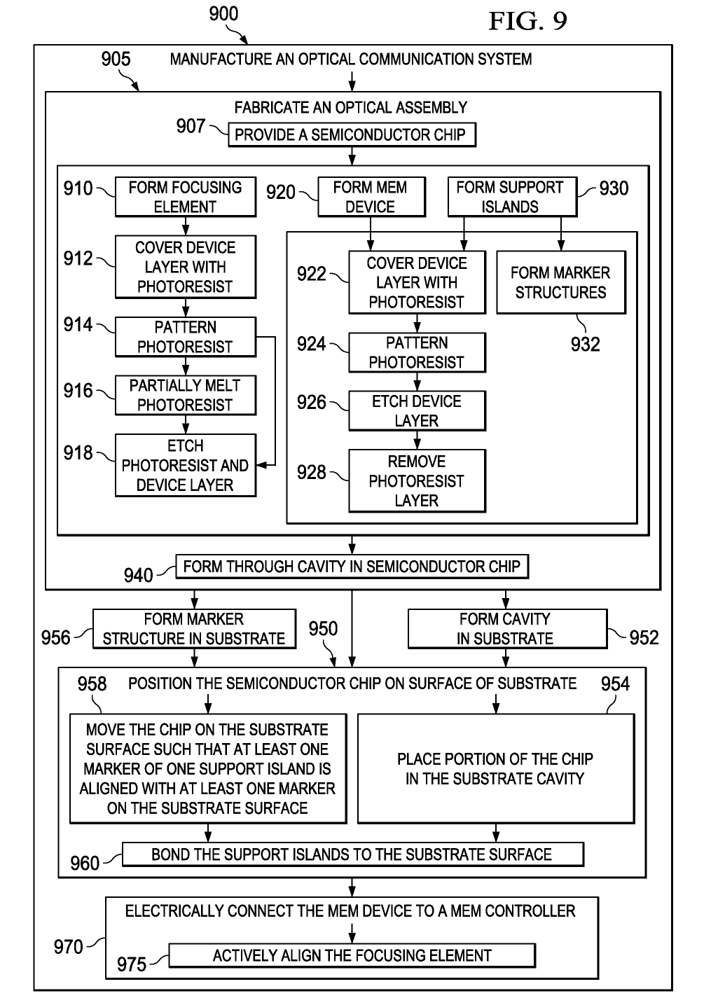

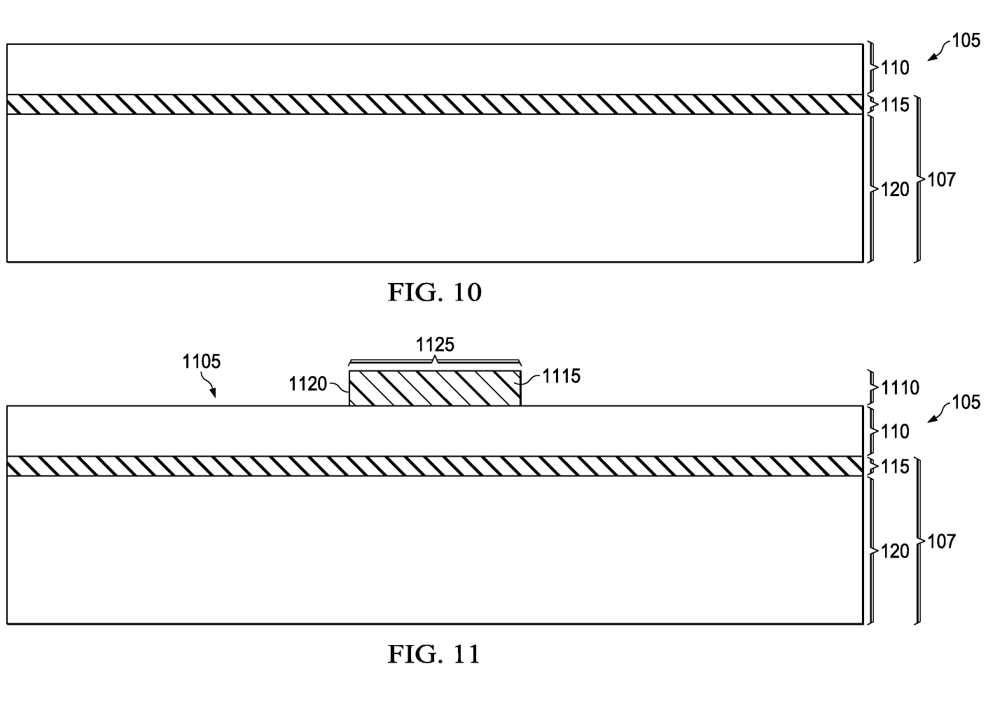

Another embodiment is a method of manufacturing an optical communication system. FIG. 9 presents a flow diagram of a method of manufacturing the communication system, including any embodiments of the system 800 and of the assemblies 100 and discussed in the context of FIGS. 1-8. FIGS. 10-17 present cross-sectional views of an optical assembly 100 of the disclosure, analogous to the optical assembly 100 shown in FIG. 2A at selected steps in the method of manufacture discussed in the context of FIG. 9.

The method 900 includes a step 905 of fabricating an optical assembly 100. As illustrated in FIG. 10, fabricating an optical assembly 100 in step 905 includes a step 907 of providing a semiconductor chip 105 (e.g., in some cases a silicon-on-insulator chip). The semiconductor chip 105 includes a handle layer 107 and a device layer 120 on the handle layer 107.

Fabricating an optical assembly 100 (step 905) includes forming, in different respective portions of the device layer 120, a focusing element 125 in step 910, a MEM device 130 in step 920, and one or more support islands 135 in step 930.

As illustrated in FIG. 9, and depicted in FIG. 11, forming the focusing element 125 in step 910 includes, in some embodiments, a step 912 of covering a surface 1105 of the device layer 110 with a photoresist layer 1110, a step 914 of patterning the photoresist layer 1110 to form a photoresist portion 1115 having a perimeter 1120 that covers a portion 1125 of the device layer 120.

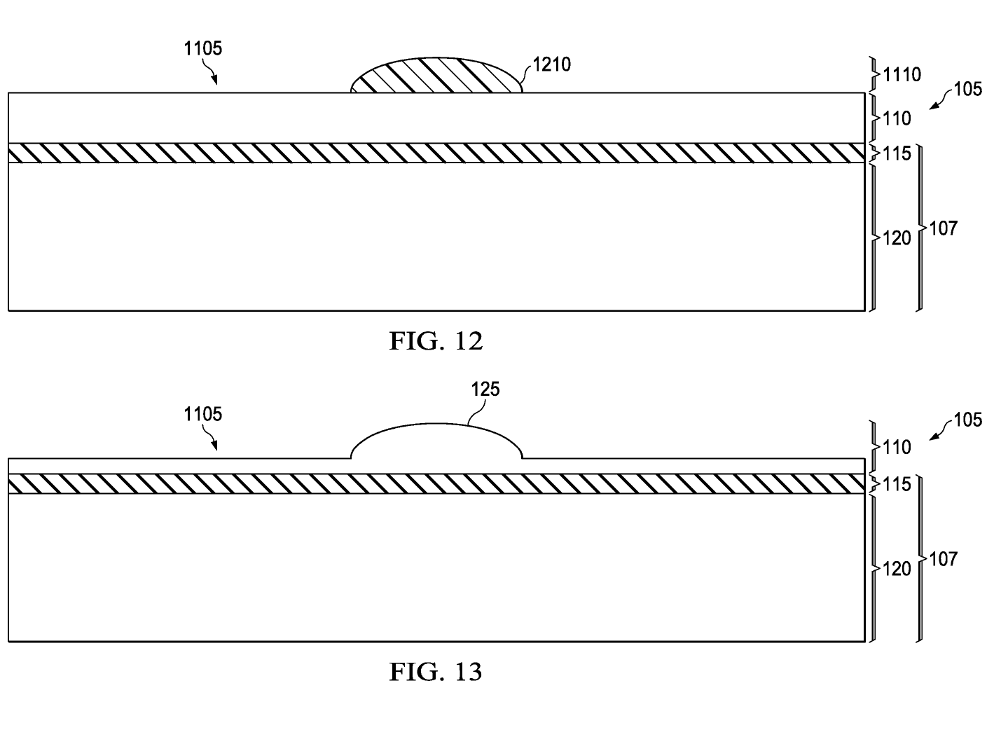

As illustrated in FIG. 9, and depicted in FIG. 12, forming the focusing element 125 in step 910 includes, in some embodiments (e.g., when the focusing element is configured as a lens), a step 916 of partially melting the photoresist portion 1115 (FIG. 11) to form a convex-shaped photoresist portion 1210.

As illustrated in FIG. 9, and depicted in FIG. 13, forming the focusing element 125 in step 910 includes, in some embodiments, a step 918 of simultaneously etching (e.g., plasma etching or any other methods familiar to those skilled in the pertinent art) the convex-shaped photoresist portion 1210 (FIG. 12) and the device layer 110, thereby transferring a convex shape to the portion 1125 (FIG. 11) of the device layer 120 covered by the convex-shaped photoresist portion 1210 (FIG. 12) to form the focusing element 125 including a lens shape.

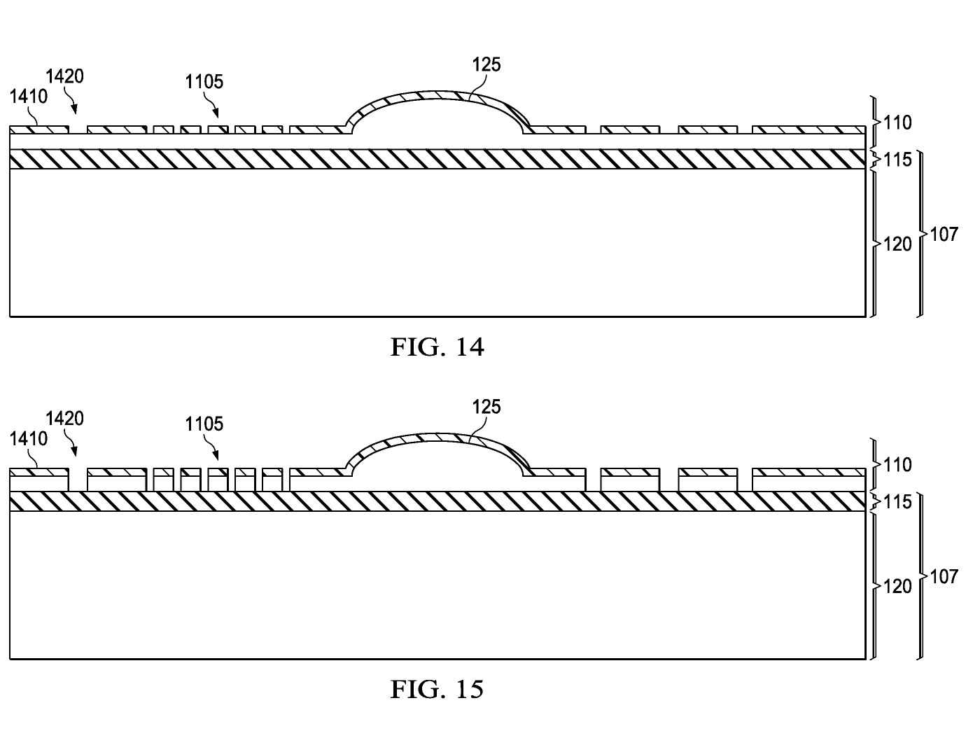

As illustrated in FIG. 9, and depicted in FIG. 14, forming the MEM device 130 in step 920 and the support islands 135 in step 930 includes, in some embodiments, a step 922 of covering a surface 1105 of the device layer 110 with a photoresist layer 1410, and, a step 924 of patterning the photoresist layer 1410 to form openings 1420 therein to define a pattern in the photoresist layer 1410 that corresponds to the MEM device 130 and the one or more support islands 135.

As illustrated in FIG. 9, and depicted in FIG. 15, forming the MEM device 130 in step 920 and the support islands 135 in step 930 includes, in some embodiments, a step 926 of etching (e.g., plasma etching or any other etching methods familiar to those skilled in the pertinent art) portions of device layer 120 not covered by the patterned photoresist layer 1410 to thereby define the MEM device 130 and the one or more support islands 135 in the device layer 120. As illustrated in FIG. 9, following the etching step 926 there can be a step 928 to remove photoresist layer 1410 from the surface 1105 of the device layer 120 using procedures familiar to one skilled in the pertinent arts.

As illustrated in FIG. 9, in some embodiments at least some of the steps 922-928 to form the MEM device 130 and support islands 135 can be common steps. Similarly in some embodiments, at least some of the steps 912-918 to form the focusing element can be common with some of the steps 922-928 to form the MEM device 130 and support islands 135.

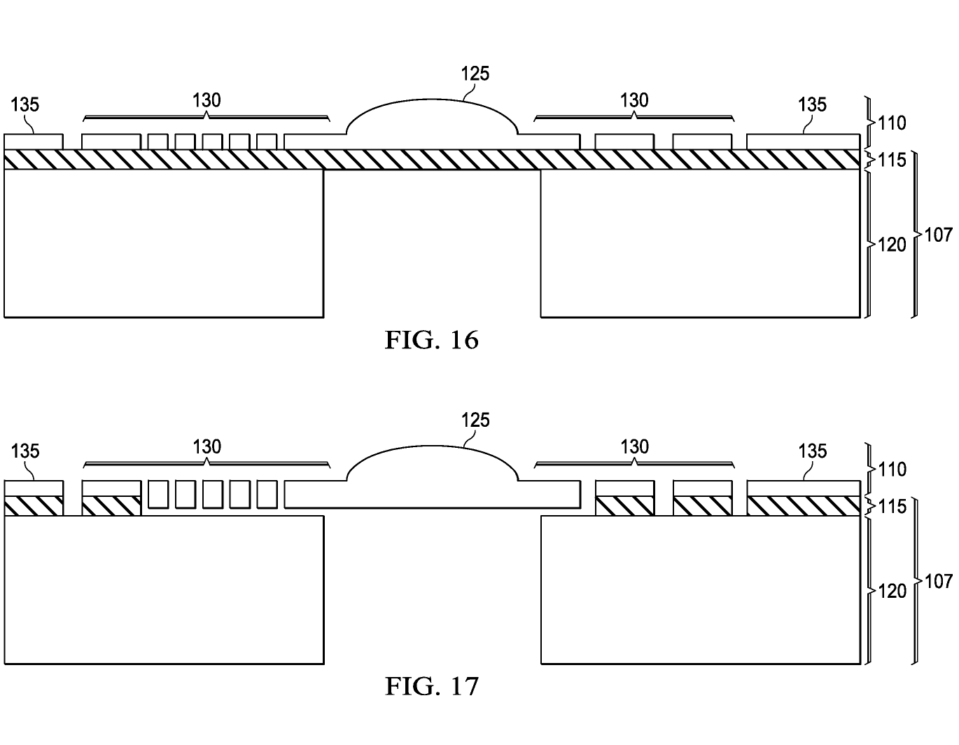

As illustrated in FIG. 9, and depicted in FIG. 16, forming the support islands 135 in step 930 includes, in some embodiments, a step 932 of forming marker structures 215 on or in at least one of the support islands 130. For example, in some embodiments, forming marker structures 215 in step 932 can be part of the steps 924, to pattern the photoresist layer 1410 form openings 1420 in the layer 1410 to define a pattern in the photoresist layer 1410 that correspond to the marker structures 215, e.g., trenches. Forming marker structures 215 in step 932, in some embodiments, can be part of the step 926 to etch portions of device layer 120 not covered by the patterned photoresist layer 1410 to thereby define the marker structures 215.

As further illustrated in FIG. 9, and depicted in FIG. 16, fabricating the optical assembly 100 in step 905, in some embodiments further includes a step 940 of forming a through-cavity 155 in the semiconductor chip 105. One of ordinary skill in the art would be familiar with lithography and etching procedures to form the back-side cavity 155.

As illustrated in FIG. 17, as part of step 940, the focusing element 125 located outside of the cavity 155, is separate from the handle layer 107. As well, as part of step 940, a portion 205 (e.g., a moveable portion) of the MEM device 135 is separate from the handle layer 107.

As further illustrated in FIG. 9, and depicted in FIG. 5, in some embodiments, the method 900 can further include a step 950 of positioning the semiconductor chip 105 on a surface 510 of a substrate 500. One skilled in the art would be familiar with various techniques using micromanipulators, such as flip-chip bonders, to place and adjust the position the chip 105 on the substrate 500. As part of step 950 the chip 105 can be positioned such that the one or more support islands 130 contact the substrate surface 510, and the focusing element 125 is held above the substrate 500. As illustrated, in some embodiments, the focusing element's 125 major planar surface 176 is substantially perpendicular the plane of contacted substrate surface 510.

With continuing reference to FIGS. 5 and 9, some embodiments of the method 900 further include a step 952 of forming a cavity 515 in the substrate 500. One of ordinary skill in the art would be familiar with lithography and etching procedures to form the cavity 515. In such embodiments, positioning the chip 105 on the substrate 500 as part of step 950 includes a step 954 of placing a portion of the chip 105 in the cavity 515. In such cases the one or more support islands 135 can contact the substrate surface 510 that corresponds to a ledge surface lying outside of the substrate cavity 515.

With continuing reference to FIGS. 5 and 9, some embodiments of the method 900 further include a step 956 of forming at least one marker structure 540 on the substrate surface 510, e.g., on the ledge surface in the vicinity of where the one or more support islands 135 will contact. One of ordinary skill in the art would be familiar with lithography and etching or depositing procedures to form the marker structure 540. In such embodiments, positioning the chip 105 on the substrate 500 as part of step 950 can include a step 958 of moving the chip 105 along the substrate surface 510 (e.g., in one dimension) such that at least one marker 215 of one support islands is aligned with at least one marker 540 on the substrate surface 510. In some embodiments, step 958 includes passively aligning the markers 215 on the one or more support islands 135 with markers 540 on the substrate surface 510, e.g., moving the chip 105 on the substrate surface 510 while no light beam travels through the focusing element 125. After passive alignment, in step 960, the part of the support islands 130 contacting the substrate surface 510 can be bonded together, e.g., by melting together two layers of solder on these surfaces.

With continuing reference to FIGS. 1, 2B, 5, 8 and 9, Some embodiments of the method 900 further include a step 970 of electrically connecting (e.g., via lines 217, 218) the MEM device 135 to a MEM controller 860, wherein electrical actuation of MEM device 135 by the MEM controller 860 changes a physical position or orientation of the focusing element 125. Some embodiments of the method 900 further include a step 975 of actively aligning the focusing element 125, by changing the physical position or orientation of the focusing element 125 (via actuation of the MEM device 135) with respect to a light beam 160 traveling through the focusing element 125, e.g. between first and second optical devices 520, 530 on the substrate 500 or part of the optical circuit 810 of the system 800.

Although the present disclosure has been described in detail, a person of ordinary skill in the relevant arts should understand that they can make various changes, substitutions and alterations herein without departing from the scope of the invention.

What is claimed is:

1. An optical assembly, comprising:
a semiconductor chip having a handle layer and a device layer on the handle layer, wherein the device layer comprises:
a focusing element,
a MEM device, wherein one portion of the MEM device is coupled to the focusing element and another portion of the MEM device is coupled to one portion of the handle layer, and the MEM device is configured to change a physical position or orientation of the focusing element in response to an electrical actuation, and
one or more support islands coupled to a different portion of the handle layer.

2. The assembly of claim 1, wherein the semiconductor chip has a through-cavity, the focusing element being located outside of the cavity and is separate from the handle layer.

3. The assembly of claim 1, wherein the focusing element, shaped as a lens, has one side with a convex-shaped major surface and an opposite side with a planar major surface.

4. The assembly of claim 3, wherein the one side having the convex shaped major surface is farther away from the handle layer than the opposite side with the planar major surface.

5. The assembly of claim 1, wherein the MEM device includes at least a first structure and a second structure, the first and second structures being separated from each other and at least one of the structures being moveable towards the other structure when the electrical actuation includes a voltage difference applied between the first and second structures.

6. The assembly of claim 1, further including:
a substrate having a surface, wherein the one or more support islands contacts the substrate surface and the focusing element is held above the substrate.

7. The assembly of claim 6, wherein the substrate further includes a cavity, a portion of the semiconductor chip being located in the cavity, and, the substrate surface that the one or more support islands contacts corresponds to a ledge surface laying outside of the substrate cavity.

8. The assembly of claim 6, further including an optical device located on the substrate surface configured to send or receive a light beam, wherein the semiconductor chip is positioned on the substrate surface such that the focusing element is in a path of the light beam.

9. The assembly of claim 8, further including a second optical device located on the substrate surface, wherein the light beam is from one of the optical device or the second optical device, and the focusing element is in the path of the light beam to the other of the optical device or the second optical device.

10. The assembly of claim 6, wherein at least one of the support islands includes markers and the substrate surface include markers, at least one of the markers of the support islands being aligned with at least one of the markers of the substrate surface.

11. An optical telecommunication system, comprising a first optical assembly, including:
a first substrate having a surface; and
a first set of semiconductor chips located on the first substrate surface, at least one of the semiconductor chips having a handle layer and a device layer on the handle layer, wherein the device layer comprises:
a focusing element,
a MEM device, wherein one portion of the MEM device is coupled to the focusing element and another portion of the MEM device is coupled to a portion of the handle layer, and the MEM device is configured to change a physical position or orientation of the focusing element in response to an electrical actuation, and
one or more support islands coupled to a different portion of the handle layer and contacting the substrate surface and holding the focusing element above the substrate; and
an optical circuit configured to send or receive a first light beam wherein the first light beam passes through one of the focusing elements of the first set of semiconductor chips.

12. The system of claim 11 further including:
a second optical assembly, including:
a second substrate having a surface; and
a second set of semiconductor chips located on the second substrate surface, at least one of the semiconductor chips having a handle layer and a device layer on the handle layer, wherein the device layer comprises:
a focusing element,
a MEM device, wherein one portion of the MEM device is coupled to the focusing element and another portion of the MEM device is coupled to the handle layer, and the MEM device is configured to change a physical position or orientation of the focusing element with respect to the output light beam in response to an electrical actuation, and
one or more support islands coupled to a different portion of the handle layer and contacting the second substrate surface and holding the focusing element above the second substrate; and wherein
the optical circuit is configured to send or receive a second light beam wherein the second light beam passes through one of the focusing element of the second set of semiconductor chips.

13. The system of claim 12, wherein the system is configured such that:
the first light beam is transmitted through at least one of the focusing elements of the first optical assembly from one of a first set of optical devices located on the substrate; and
the second light beam is transmitted through at least one of the focusing elements the second optical assembly to one of a second set of optical devices located on the second substrate.

14. The system of claim 11, further including a MEM controller, wherein the MEM controller is configured to separately apply a voltage to each one of the MEM devices of first set of semiconductor chips.

15. The system of claim 14, further including light sensors configured to receive at least a portion of the input light beam after traveling through one of the focusing element of the first set of semiconductor chips.

16. A method of manufacturing an optical communication system, comprising:
fabricating an optical assembly, including
providing a semiconductor chip, wherein the semiconductor chip includes a handle layer and a device layer on the handle layer;
forming, in different respective portions of the device layer:
a focusing element,
a MEM device, wherein one portion of the MEM device is coupled to the focusing element and another portion of the MEM device is coupled to one portion of the handle layer, and
one or more support islands coupled to a different portion of the handle layer.

17. The method of claim 16, wherein forming the focusing element as a lens includes:
covering a surface of the device layer with a photoresist layer;
patterning the photoresist layer to form a photoresist portion having a perimeter that covers a portion of the device layer;
partially melting the photoresist portion to form a convex-shaped photoresist portion; and then
simultaneously etching the convex-shaped photoresist portion and the device layer, thereby transferring a convex shape to the portion of the device layer covered by the convex-shaped photoresist portion and removing the photoresist layer from the surface of the device layer.

18. The method of claim 16, wherein forming the MEM device and the one or more support islands includes:
covering a surface of the device layer with a photoresist layer;
patterning the photoresist layer to form openings therein to define a pattern in the photoresist layer that corresponds the MEM device and the one or more support islands; and
etching portions of device layer not covered by the patterned photoresist layer to thereby define the MEM device and the one or more support islands in the device layer; and
removing the photoresist layer from the surface of the device layer.

19. The method of claim 16, wherein forming the one or more support islands includes forming marker structures in at least one of the support islands.

20. The method of claim 16, further including forming a through-cavity in the semiconductor chip, the focusing element being located outside of the cavity and separate from the handle layer and a portion of the MEM device is separate from the handle layer.
